(19) United States
(12) Patent Application Publication
(10) Pub. No.: US 2011/0095755 A1
(43) Pub. Date: Apr. 28, 2011

(54) FIBER CELL, MAGNETIC SENSOR, AND MAGNETIC FIELD MEASURING APPARATUS

(75) Inventor: Yoshiyuki MAKI, Hino (JP)

(73) Assignee: SEIKO EPSON CORPORATION, Tokyo (JP)

(21) Appl. No.: 12/908,959

(22) Filed: Oct. 21, 2010

(30) Foreign Application Priority Data
Oct. 22, 2009 (JP) 2009-243105

(51) Int. Cl. G01R 33/02; G02B 6/02

(52) U.S. Cl. 324/244.1; 385/123

(57) ABSTRACT

A fiber cell includes: an optical fiber including a cladding that totally reflects light, a core through which the totally reflected light propagates, and an internal cavity formed in the core; and an alkali metal atom sealed in the internal cavity.

### CROSS-REFERENCE TO RELATED APPLICATIONS

This application claims the benefit of Japanese Patent Application No. 2009-243105 filed Oct. 22, 2009. The disclosures of the above application are incorporated herein by reference.

### BACKGROUND

1. Technical Field

The present invention relates to a fiber cell, a magnetic sensor, and a magnetic field measuring apparatus, and more particularly to a magnetic sensor and a magnetic field measuring apparatus using a fiber cell produced by sealing an alkali metal atom in part of an optical fiber to detect the strength of an external magnetic field.

2. Related Art

The oscillatory frequency of an atomic oscillator is produced with reference to the difference in energy between two ground levels of an alkali metal atom (ΔE12). Since the value of ΔE12 changes with the strength of external magnetism and due to fluctuation thereof, the cell in the atomic oscillator is surrounded by a magnetic shield so that the external magnetism does not affect the atomic oscillator. Conversely, the atomic oscillator with no magnetic shield can be a magnetic sensor that detects change in ΔE12 based on change in oscillatory frequency to measure the strength and variation of external magnetism. However, electronic parts in the atomic oscillator also produce magnetic fields, and magnetic fields other than a magnetic field to be measured are present around the cell. It is therefore difficult to accurately measure only the magnetic field to be measured.

JP-A-2007-167616 discloses a magnetic fluxmeter based on optical pumping.

The related art described in JP-A-2007-167616 excels in that a high-sensitivity magnetic sensor is formed by using an interaction between an alkali metal and light. The related art is, however, problematic in terms of optical axis alignment because it employs a configuration in which a laser beam is radiated into space, collimated through a lens, and received by a photodetector. The related art also has a problem of vulnerability to magnetic noise produced, for example, by the photodetector because the laser and a peripheral circuit thereof are disposed in the vicinity of the cell of the magnetic sensor.

### SUMMARY

An advantage of some aspects of the invention is to provide a magnetic sensor and a magnetism measuring apparatus that can accurately measure the magnetic field at a measurement point or in a measurement area without any influence of unwanted external magnetic fields by using a fiber cell obtained by sealing an alkali metal atom in part of a fiber to detect the strength of an external magnetic field.

The invention can be implemented in the following forms or application examples.

### Application Example 1

This application example is directed to a fiber cell including an optical fiber including a cladding that totally reflects light, a core through which the totally reflected light propagates, and an internal cavity formed in the core, and an alkali metal atom sealed in the internal cavity.

An optical fiber can propagate light without any influence of electric and magnetic fields. To sense the strength of magnetism, a cell in which an alkali metal atom is sealed needs to be integrated with a fiber. To this end, in this application example of the invention, an internal cavity is formed through a central portion of the core of an optical fiber, and an alkali metal atom is sealed in the internal cavity. Both ends of the internal cavity are then blocked with the cores of other optical fibers. A magnetic sensor entirely formed of optical fibers is thus achieved.

### Application Example 2

This application example is directed to the fiber cell of the above application example, wherein the optical fiber cell is wound multiple times.

To improve the S/N ratio of an optical output signal produced in an EIT phenomenon, it is necessary to increase the number of alkali metal atoms that interact with laser light. To this end, the length of the fiber cell, in which the alkali metal atom is sealed, is increased, and the thus lengthened fiber cell is wound multiple times in this application example of the invention. In this way, the S/N ratio of an optical output signal can be improved, and magnetism detection sensitivity can be increased.

### Application Example 3

This application example is directed to a magnetic sensor including the fiber cell according to Application Example 1 or 2 as a sensor that detects the strength of an external magnetic field.

The fiber cell, in which the alkali metal atom is sealed, works as a sensor that detects magnetism. It has been known that the oscillatory frequency of an atomic oscillator that the difference in energy between two ground levels of an atom changes with the strength of external magnetism and due to fluctuation thereof. It is therefore preferable to detect magnetism exactly at the location where actual measurement is made. To this end, the configuration of the fiber cell is divided into two portions in this application example of the invention, that is, a second optical fiber, in which an alkali metal atom is sealed, and first optical fibers, which are connected to the respective ends of the second optical fiber and serve to propagate light. The resultant magnetic sensor can therefore accurately detect the magnetic field in a measurement area without detecting any unwanted magnetic field in the area outside the measurement area.

### Application Example 4

This application example is directed to the magnetic sensor of the above application example, wherein the fiber cell according to Application Example 1 or 2 is disposed in a grid pattern so that the strength of a magnetic field can be measured across a two-dimensional area.

One fiber cell suffices when there is only one measurement point. When there is a measurement area that spreads two-dimensionally, however, using only one fiber cell requires a long measurement period and reduces measurement precision. In this application example of the invention, the strength of a magnetic field can be measured across a two-dimensional area by arranging the fiber cells in a grid pattern. The measurement can therefore be simultaneously and accurately made at a plurality of locations.

### Application Example 5

This application example is directed to a magnetism measuring apparatus including alight source that emits a pair of resonance light beams that allow an electromagnetically induced transparency phenomenon to occur in an alkali metal atom, the magnetic sensor according to Application Example 3 or 4, a magnetic field generator that generates a static magnetic field that allows Zeeman splitting to occur in the alkali metal atom, a photodetector that detects the pair of resonance light beams having exited through the magnetic sensor, a frequency sweeper that sweeps the difference in frequency between the pair of resonance light beams, and a recorder that records a plurality of local maximums of the magnitude of an output from the photodetector in synchronization with the sweeping operation of the difference in frequency. The strength of an external magnetic field is measured based on the difference in frequency corresponding to the plurality of local maximums.

To provide a magnetism measuring apparatus using the magnetic sensor according to Application Example 5 of the invention, the magnetism measuring apparatus includes a light source that emits a pair of resonance light beams toward the magnetic sensor (optical fiber), a photodetector that detects the intensity of the pair of resonance light beams having exited through the magnetic sensor, a sweep circuit that sweeps a microwave to induce an electromagnetically induced transparency phenomenon, a magnetic field generator that generates a static magnetic field that allows Zeeman splitting to occur in the alkali metal atom, and a peak detecting circuit that stores local maximums of the signal outputted from the photodetector. The peak detecting circuit detects a plurality of local maximums obtained when Zeeman splitting occurs, and the strength of magnetism is determined from the difference in cycle between the peaks. That is, the strength of the magnetism is determined to be larger when the difference in cycle between the peaks is larger.

### BRIEF DESCRIPTION OF THE DRAWINGS

The invention will be described with reference to the accompanying drawings, wherein like numbers reference like elements.

FIGS. 1A and 1B show the configuration of part of a fiber cell according to the invention.

FIGS. 2A and 2B show the configuration of a typical optical fiber: FIG. 2A is a cross-sectional view of the optical fiber taken along the circumferential direction and FIG. 2B is a cross-sectional view of the optical fiber taken along the axial direction (B-B).

FIG. 3 shows an overall configuration of a magnetic sensor according to the invention.

FIG. 4A is a block diagram showing the configuration of a magnetism measuring apparatus according to a first embodiment of the invention, and FIG. 4B shows the configuration of the magnetic sensor according to the invention but wound multiple times.

FIG. 5 shows an example in which the fiber cell shown in FIG. 4B is disposed in a grid pattern so that 9 fiber cells are arranged in an area A.

FIG. 6 describes another method for driving the fiber cells arranged in a grid pattern.

FIG. 7 is a block diagram showing the configuration of a magnetism measuring apparatus according to a second embodiment of the invention.

FIG. 8A describes an EIT signal obtained when Zeeman splitting occurs, and FIG. 8B shows the relationship between magnetic flux density and Zeeman splitting.

FIG. 9A is a block diagram showing the configuration of a magnetism measuring apparatus including an oscilloscope 28 in place of a peak detecting circuit 25 shown in FIG. 7, FIG. 9B shows the waveforms of a frequency sweep control signal and a trigger signal, and FIG. 9C shows an EIT signal obtained when Zeeman splitting occurs and displayed on the oscilloscope 28.

### DESCRIPTION OF EXEMPLARY EMBODIMENTS

The invention will be described below in detail with reference to embodiments shown in the drawings. It is, however, noted that the components and the types, combinations, shapes, relative arrangements, and other factors thereof described in the embodiments are not intended to limit the scope of the invention only thereto but are presented only by way of example unless otherwise specifically described.

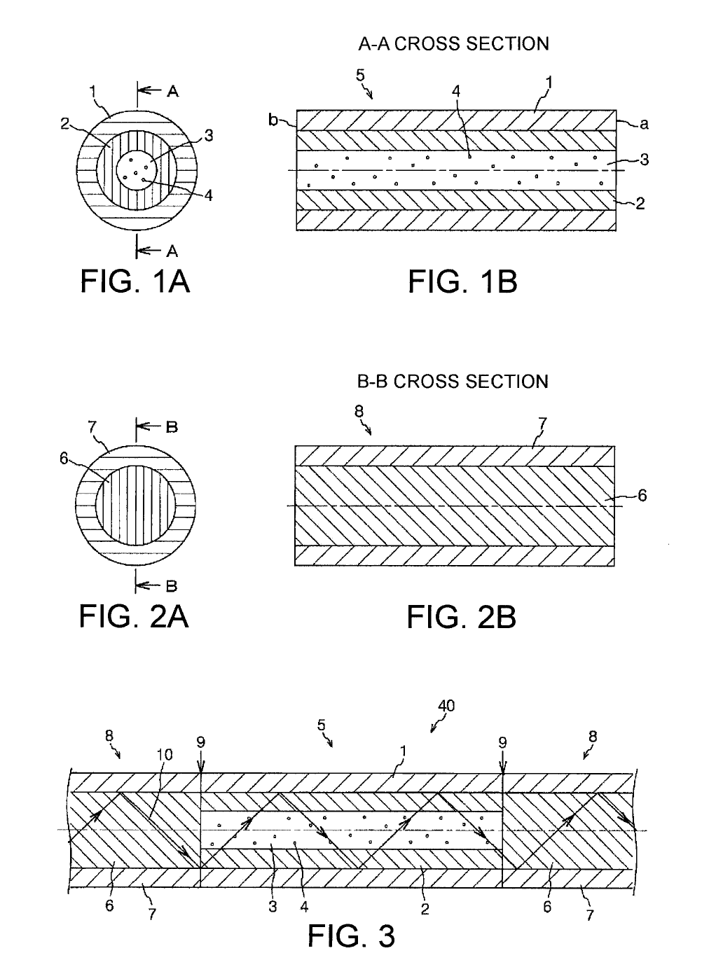

FIGS. 1A and 1B show the configuration of part of a fiber cell according to the invention. FIG. 1A is a cross-sectional view of the fiber cell taken along the circumferential direction, and FIG. 1B is a cross-sectional view of the fiber cell taken along the axial direction (A-A). The fiber cell 5 includes a tubular cladding 1 that totally reflects light, a core 2 which is formed inside the tube that forms the cladding 1 and through which the totally reflected light propagates, and an internal cavity 3 which extends through a substantially central portion of the core 2 and through which the light incident from the core 2 propagates. An alkali metal atom 4 is sealed in internal cavity 3, and each of the ends “a” and “b” of the internal cavity 3 is blocked by the core of another optical fiber (not shown) (see FIGS. 2A and 2B).

An optical fiber can propagate light without any influence of electric and magnetic fields. To sense the strength of magnetism, the cell in which the alkali metal atom 4 is sealed needs to be integrated with a fiber. To this end, in the present embodiment, the internal cavity 3 is formed through a central portion of the core 2 of the fiber cell 5, and the alkali metal atom 4 is sealed in the internal cavity 3. Both ends of the internal cavity 3 are then blocked with the cores of other optical fibers (see FIGS. 2A and 2B). A magnetic sensor entirely formed of optical fibers is thus achieved.

FIGS. 2A and 2B show the configuration of a typical optical fiber. FIG. 2A is a cross-sectional view of the optical fiber taken along the circumferential direction, and FIG. 2B is a cross-sectional view of the optical fiber taken along the axial direction (B-B). The optical fiber 8 includes a cladding 7 that totally reflects light and a core 6 through which the totally reflected light propagates.

FIG. 3 shows an overall configuration of a magnetic sensor according to the invention. The magnetic sensor 40 is assembled by bonding each of the ends of the fiber cell 5 shown in FIGS. 1A and 1B to the optical fiber 8 shown in FIGS. 2A and 2B with a bonding portion 9 therebetween and sealing the alkali metal atom 4 in the internal cavity 3. The magnetic sensor 40 can be readily manufactured by using a typical method in which optical fibers are bonded to each other in an atmosphere containing the alkali metal atom 4. In the magnetic sensor 40, for example, laser light 10 propagating through the left side is totally reflected off the cladding 7, propagates through the core 6, passes through the left bonding portion 9, and propagates through the fiber cell 5. The laser light 10 travelling into the fiber cell 5 is totally reflected off the cladding 1 and passes through the internal cavity 3 many times while interacting with the alkali metal atom 4 in the internal cavity 3. As a result, the magnitude of an EIT signal increases and the S/N ratio thereof is improved. The laser light 10 having exited from the fiber cell 5 travels into the right optical fiber, is totally reflected off the cladding 7, and propagates through the core 6.

The fiber cell 5, in which the alkali metal atom 4 is sealed, works as a sensor that detects magnetism. It has been known that the oscillatory frequency of an atomic oscillator that the difference in energy between two ground levels of an atom changes with the strength of external magnetism and due to fluctuation thereof. It is therefore preferable to detect magnetism exactly at the location where actual measurement is made. To this end, the configuration of the fiber cell 5 is divided into two portions in the present embodiment, that is, the fiber cell 5, in which the alkali metal atom 4 is sealed, and the optical fibers 8, which are connected to the respective ends of the fiber cell 5 and serve to propagate light. The resultant magnetic sensor can therefore accurately detect the magnetic field in a measurement area without detecting any unwanted magnetic field in the area outside the measurement area.

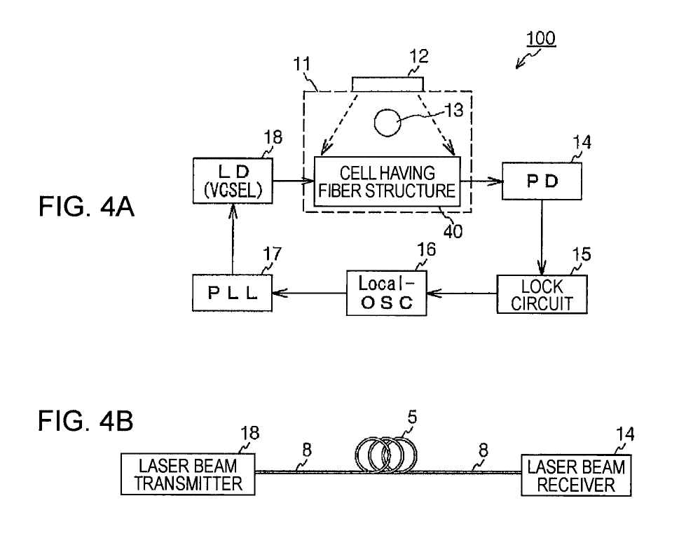

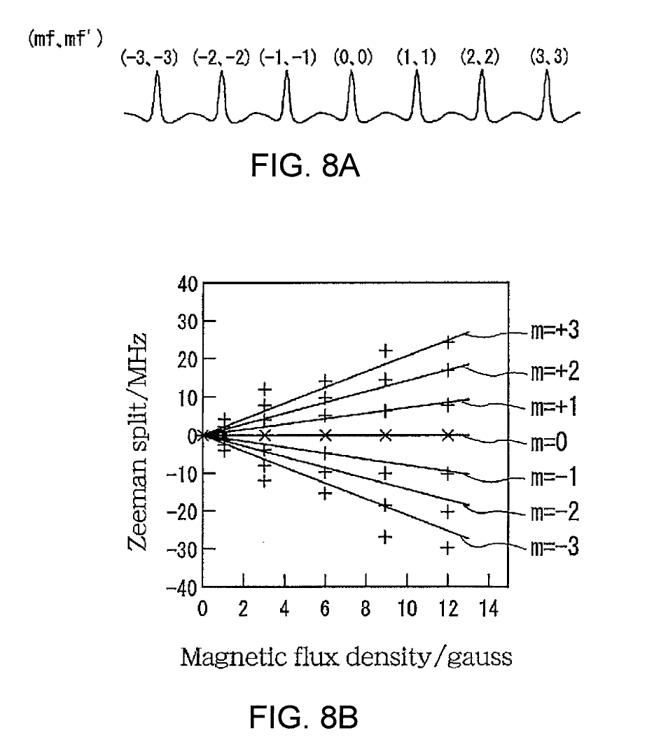

FIG. 4A is a block diagram showing the configuration of a magnetism measuring apparatus according to a first embodiment of the invention. A magnetism measuring apparatus 100 includes a laser beam transmitter LD (light source) that emits a pair of resonance light beams that allow an EIT phenomenon (electromagnetically induced transparency phenomenon) to occur in an alkali metal atom, the magnetic sensor 40 shown in FIG. 3, a magnetic field generator 12 that generates a static magnetic field that allows Zeeman splitting to occur in the alkali metal atom, a laser beam receiver PD (photodetector) 14 that detects the pair of resonance light beams having exited through the magnetic sensor 40, a lock circuit 15 that senses an EIT signal and locks an oscillatory frequency, a local oscillator 16 that controls the oscillatory frequency based on the voltage across the lock circuit 15, and a PLL 17 that multiplies the frequency of the local oscillator 16 to produce a high frequency. The magnetic sensor 40 is placed in a measurement chamber 11 to shield it from unwanted external magnetic fields and is controlled so that the magnetic field generator 12 induces Zeeman splitting. The magnetic sensor 40 senses the change in the magnetic field produced by an object under measurement 13. Zeeman splitting is now described below. Zeeman splitting is a phenomenon in which when a magnetic field is applied externally to an alkali metal atom, the ground level of the alkali metal atom is split into a plurality of levels different from one another in terms of energy state. Zeeman splitting also changes the difference in energy between two ground levels of the alkali metal atom (ΔE12), which is a resonance frequency. FIG. 8B shows Zeeman splitting that occurs in a cesium atom. The horizontal axis of FIG. 8B represents the strength of a magnetic field, and the vertical axis represents the change indifference in energy between split ground levels (change in resonance frequency). In FIG. 8B, m represents what is called a magnetic quantum number, and it is known that there are only seven resonance frequencies corresponding to combinations of the same magnetic quantum number m. When the strength of the magnetic field is zero, the seven resonance frequencies coincide with one another and are hence degenerate. When the strength of the magnetic field changes, the resonance frequencies change accordingly at respective rates different from one another. Now, consider one of the magnetic quantum numbers (m=+3, for example) except the magnetic quantum number m=0. The output frequency from the local oscillator 16 (output frequency from PLL 17) is controlled in such a way that the resonance frequency (EIT signal) corresponding to the combination of the magnetic quantum number m=+3 is selected as the output frequency. For example, the oscillatory frequency of the local oscillator 16 may be limited within a certain range. Consider now a state in which the magnetic field produced by the object under measurement 13 is superimposed on the static magnetic field produced by the magnetic field generator 12, and it will be found that the oscillatory frequency of the local oscillator 16 changes with the strength of the magnetic field produced by the object under measurement 13. The strength of the magnetic field produced by the object under measurement 13 can therefore be detected by measuring the change in frequency of the local oscillator 16. It is noted that any magnetic quantum number m may be used except zero.

FIG. 4B shows the configuration of the magnetic sensor according to the invention but wound multiple times. To improve the S/N ratio of an optical output signal produced in an EIT phenomenon, it is necessary to increase the number of alkali metal atoms that interact with the laser light. To this end, the length of the fiber cell 5, in which the alkali metal atom is sealed, is increased, and the thus lengthened fiber cell 5 is wound multiple times in the present embodiment. In this way, the S/N ratio of an optical output signal can be improved, and magnetism detection sensitivity can be increased.

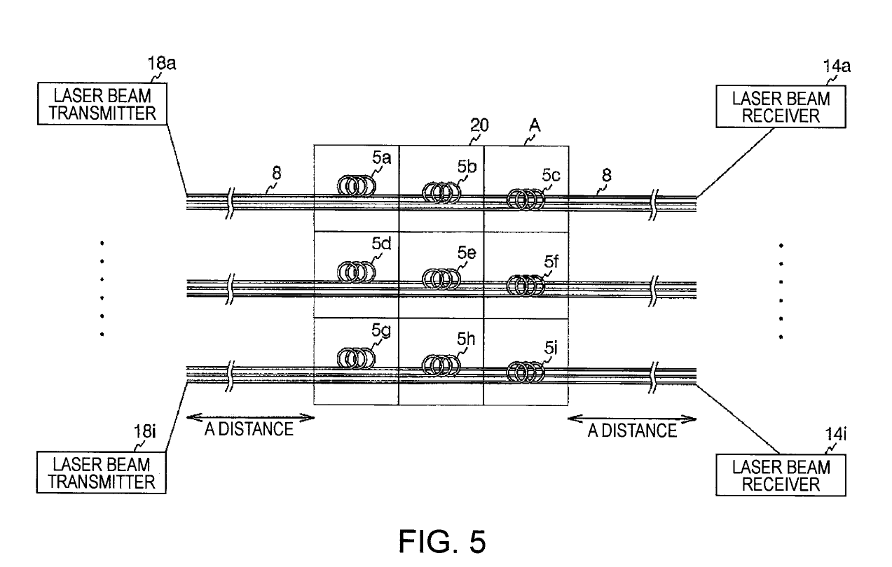

FIG. 5 shows an example in which the fiber cell shown in FIG. 4B is disposed in a grid pattern so that 9 fiber cells 5a to 5i are arranged in an area A. Each of the fiber cells has one end to which the corresponding one of laser beam transmitters (LDs) 18a to 18i is connected and the other end to which the corresponding one of laser beam receivers (PDs) 14a to 14i is connected. That is, one fiber cell suffices when there is only one measurement point. When there is a measurement area that spreads two-dimensionally, however, using only one fiber cell requires a long measurement period and reduces measurement precision. In the present embodiment, the strength of a magnetic field can be measured across the two-dimensional area A by arranging the fiber cells 5a to 5i in a grid pattern. The measurement can therefore be simultaneously and accurately made at a plurality of locations.

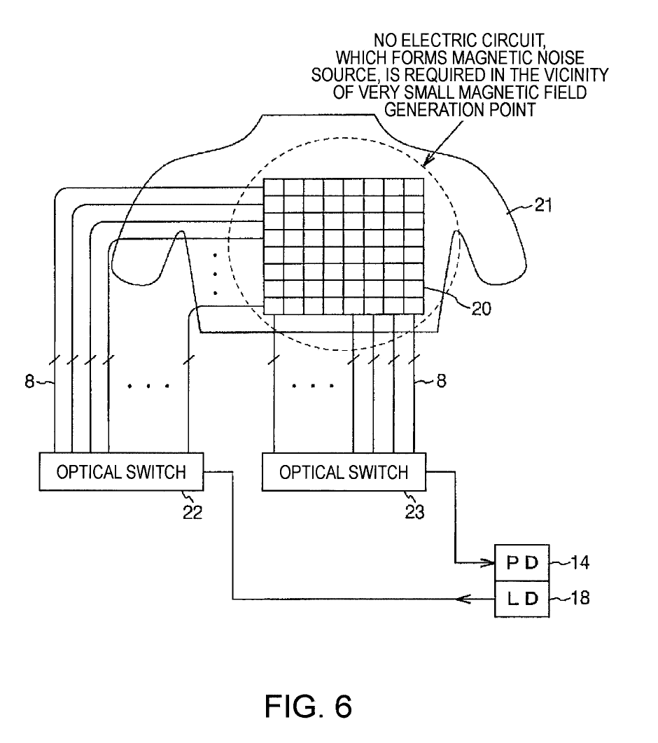

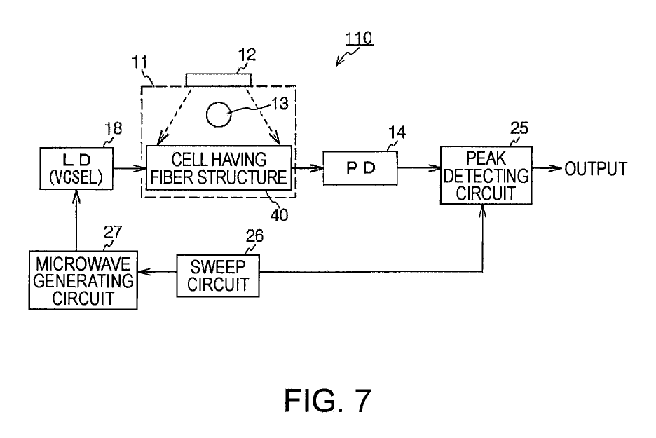

FIG. 6 describes another method for driving the fiber cells arranged in a grid pattern. In FIG. 5, since the fiber cells require the respective laser beam transmitters 18 and the laser beam receivers 14, the number of laser beam transmitters 18 and laser beam receivers 14 needs to be equal to the number of fiber cells, disadvantageously resulting in an increased cost of the overall apparatus. To address the problem, in the present embodiment, the fiber cells 20 arranged in a grid pattern are attached to an apparatus 21 to which fiber cells can be attached, and the fiber cells 8 are connected to respective optical switches 22 and 23 in a one-to-one relationship. Laser light emitted from the LD 18 is inputted to an input terminal of the group of optical switches 22, and the output from the group of optical switches 23 is incident on the PD 14. Although not shown, the apparatus further includes a control circuit for selecting the optical switches and 23 in synchronization with a timing signal. The configuration allows information from the magnetic sensors arranged in a grid pattern to be acquired without an increase in the number of LDs 18 and PDs 14.

Each of the optical switches 22 and 23 is formed, for example, of a MEMS optical switch formed of a micro mirror that reflects a light beam. That is, as another method for switching an optical signal, the optical signal is temporarily converted into an electric signal, and the state of the electric signal is then changed between on and off. To convert an optical signal into an electric signal, however, a photoelectric conversion device is required and part of the signal is lost in the conversion process. To address the problem, a MEMS optical switch is used to directly switch light in the present embodiment. Since no photoelectric conversion device is required in this configuration, a low-loss, compact switch is achieved.

FIG. 7 is a block diagram showing the configuration of a magnetism measuring apparatus according to a second embodiment of the invention. A magnetism measuring apparatus 110 includes an LD 18 that emits a pair of resonance light beams that allow an EIT phenomenon to occur in an alkali metal atom, the magnetic sensor 40 shown in FIG. 3, a magnetic field generator 12 that generates a static magnetic field that allows Zeeman splitting to occur in the alkali metal atom, a PD 14 that detects the pair of resonance light beams having exited through the magnetic sensor 40, a sweep circuit (frequency sweeper) 26 that sweeps the difference in frequency between the pair of resonance light beams, a microwave generating circuit 27 that generates a microwave, and a peak detecting circuit (recorder) 25 that records a plurality of local maximums of the magnitude of the output from the PD 14 in synchronization with the seeping operation of the difference in frequency. The magnetism measuring apparatus 110 measures the strength of an external magnetic field based on the difference in frequency corresponding to the plurality of local maximums.

To provide a magnetism measuring apparatus using the magnetic sensor 40 according to the second embodiment of the invention, the magnetism measuring apparatus includes the LD 18 that emits a pair of resonance light beams toward the magnetic sensor 40, the PD 14 that detects the intensity of the pair of resonance light beams having exited through the magnetic sensor 40, the sweep circuit 26 that sweeps a microwave to produce an EIT signal, the magnetic field generator 12 that generates in advance a static magnetic field that allows Zeeman splitting to occur in the alkali metal atom, and the peak detecting circuit 25 that stores local maximums of the signal outputted from the PD 14. The peak detecting circuit 25 detects an EIT signal (plurality of local maximums) obtained when Zeeman splitting occurs, and the time interval between the generated peaks (time difference) is stored as a reference value. Since the time interval between the generated peaks changes with the strength of the magnetic field produced by the object under measurement 13, the strength of the magnetism produced by the object under measurement 13 is determined by comparing the change in the time interval with the reference value. That is, the strength of the magnetism is determined to be larger when the change in time interval between the generated peaks (time difference) is larger.

FIG. 8A describes an EIT signal obtained when Zeeman splitting occurs. FIG. 8B shows the relationship between magnetic flux density and Zeeman splitting. That is, a CPT atomic oscillator produces an EIT signal (local maximum) in an electromagnetically induced transparency phenomenon when the output signal from the atomic oscillator is synchronized. The spectrum of the EIT signal has a high magnitude but has a wide width at half maximum because a plurality of ground levels is degenerate. A sync detector detects that the output signal from the atomic oscillator is synchronized, and a magnetic field having a predetermined strength is applied to the magnetic sensor (fiber cell) 40. When the magnetic field is applied to the gaseous alkali metal atom in the magnetic sensor, the spectrum of the EIT signal is split into, for example, 7 ground levels having different energy levels when the alkali metal atom is cesium, (see FIG. 8A). This phenomenon is called Zeeman splitting. According to the relationship between magnetic flux density and Zeeman splitting shown in FIG. 8B, the width of Zeeman splitting (difference infrequency corresponding to difference in energy) changes in proportion to the magnetic flux density. In FIG. 8B, m is called a magnetic quantum number.

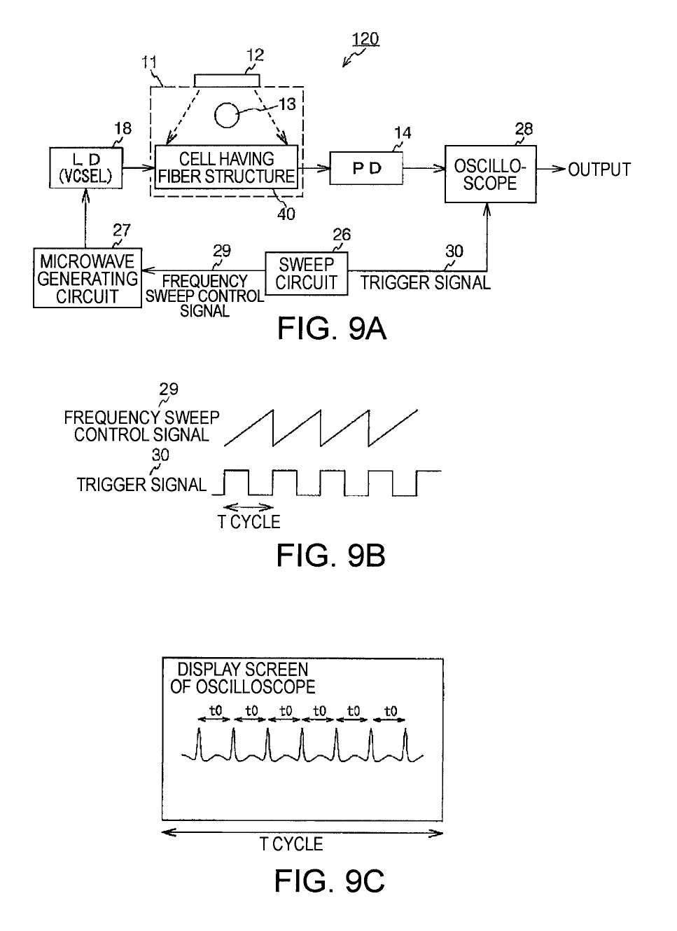

FIG. 9A is a block diagram showing the configuration of a magnetism measuring apparatus including an oscilloscope 28 in place of the peak detecting circuit 25 shown in FIG. 7. In the following description, the same components as those shown in FIG. 7 have the same reference characters. The sweep circuit 26 outputs a trigger signal 30 for synchronizing a frequency sweep control signal 29 with the oscilloscope 28. FIG. 9B shows the waveforms of the frequency sweep control signal and the trigger signal. The frequency sweep control signal is a sawtooth wave that linearly changes in a cycle T, and the trigger signal is a rectangular wave whose duty is 50% of the cycle T. FIG. 9C shows an EIT signal obtained when Zeeman splitting occurs and displayed on the oscilloscope 28. It is thus possible to observe in real time that the interval t0 between the peaks of the waveform displayed on the oscilloscope changes with the strength of the magnetism produced by the object under measurement 13.

What is claimed is:

1. A fiber cell comprising:
an optical fiber including
a cladding that totally reflects light,
a core through which the totally reflected light propagates, and
an internal cavity formed in the core; and
an alkali metal atom sealed in the internal cavity.

2. The fiber cell according to claim 1,
wherein the optical fiber is wound multiple times.

3. A magnetic sensor comprising:
the fiber cell according to claim 1,
wherein the fiber cell works as a sensor that detects the strength of an external magnetic field.

4. The magnetic sensor according to claim 3,
wherein the fiber cell according to claim 1 is disposed in a grid pattern so that the strength of a magnetic field can be measured across a two-dimensional area.

5. A magnetism measuring apparatus comprising:
a light source that emits a pair of resonance light beams that allow an electromagnetically induced transparency phenomenon to occur in an alkali metal atom;
the magnetic sensor according to claim 3;
a magnetic field generator that generates a static magnetic field that allows Zeeman splitting to occur in the alkali metal atom;
a photodetector that detects the pair of resonance light beams having exited through the magnetic sensor;
a frequency sweeper that sweeps the difference in frequency between the pair of resonance light beams; and
a recorder that records the time interval between a plurality of local maximums of the magnitude of an output from the photodetector in synchronization with the sweeping operation of the difference in frequency,
wherein the strength of an external magnetic field is measured based on the time interval between the plurality of local maximums.
